(19) United States
(12) Patent Application Publication
(10) Pub. No.: US 2015/0013606 A1
(43) Pub. Date: Jan. 15, 2015

(54) FILM FORMING SYSTEM

(71) Applicant: Tokyo Electron Limited, Tokyo (JP)

(72) Inventor: Takashi TERADA, Koshi City (JP)

(21) Appl. No.: 14/312,946

(22) Filed: Jun. 24, 2014

(30) Foreign Application Priority Data
Jul. 11, 2013 (JP) 2013-145297
May 22, 2014 (JP) 2014-106087

(51) Int. Cl. H01L 21/02; H01L 21/67

(52) U.S. Cl. CPC H01L 21/02263; H01L 21/02065; H01L 21/67092; H01L 21/67098
USPC 118/719; 118/725

(57) ABSTRACT

A film forming system includes: a treatment station that performs a predetermined treatment on a substrate; and a transfer-in/out station configured to retain a plurality of substrates and transfer the substrates in/out from/to the treatment station. The treatment station includes: a coating apparatus that applies a coating solution onto a front surface of the substrate to form a containing film; a thermal treatment apparatus that thermally treats the substrate on which the coating film has been formed; a grinding apparatus that grinds the coating film on the front surface of the substrate which has been thermally treated; a cleaning apparatus that cleans the substrate whose coating film has been ground; and a transfer region for transferring the substrate.

### CROSS REFERENCE TO RELATED APPLICATIONS

This application is based upon and claims the benefit of priority of the prior Japanese Patent Application No. 2013-145297, filed in Japan on Jul. 11, 2013, and the prior Japanese Patent Application No. 2014-106087, filed in Japan on May 22, 2014, the entire contents of which are incorporated herein by reference.

### BACKGROUND OF THE INVENTION

1. Field of the Invention

The present invention relates to a film forming system for forming a coating film on a substrate having a plurality of circuits formed on a front surface thereof.

2. Description of the Related Art

For example, in a manufacturing process of a semiconductor device, after a plurality of circuits are formed on the front surface of a semiconductor wafer (hereinafter, referred to as a “wafer”), a so-called post process is performed. In the post-process, the wafer is cut into a plurality of semiconductor chips (hereinafter, referred to as “chips”) and then the chips are assembled. In assembly of the chips, for example, a coating film is formed for each of the chips to seal the circuits.

The film forming treatment of the coating film is performed by supplying and filling a coating solution between the chips and a wiring substrate and then heat-treating the coating solution (Japanese Patent Application Publication No. 2000-252325).

### SUMMARY OF THE INVENTION

Incidentally, higher integration of semiconductor devices is demanded and the diameter of the wafer becomes larger in recent years. In the case where the coating film is formed on a chip basis as in the prior art under such circumstances, a lot of time is required to perform the film forming treatment on all of the chips because the number of chips is large.

Further, the conventional film forming treatment of the coating film is not performed in one system, in which efficient performance of a series of film forming treatment is not taken into consideration. Therefore, there is room for improvement in throughput of the whole film forming treatment.

The present invention has been made in consideration of the above points, and its object is to efficiently perform film formation of a coating film on a substrate having a plurality of circuits formed on a front surface thereof so as to improve the throughput of the film forming treatment.

To achieve the above object, the present invention is a film forming system for forming a coating film on a substrate having a plurality of circuits formed on a front surface thereof, the system including: a treatment station that performs a predetermined treatment on the substrate; and a transfer-in/out station configured to retain a plurality of substrates and transfer the substrates in/out from/to the treatment station, the treatment station including: a coating apparatus that applies a coating solution onto the front surface of the substrate to form a containing film; a thermal treatment apparatus that thermally treats the substrate on which the coating film has been formed; a grinding apparatus that grinds the coating film on the front surface of the substrate which has been subjected to the thermal treatment; a cleaning apparatus that cleans the substrate whose coating film has been ground; and a transfer region for transferring the substrate to the coating apparatus, the thermal treatment apparatus, the grinding apparatus, and the cleaning apparatus.

According to the present invention, it is possible to apply a coating solution onto the front surface of the substrate to form a coating film in a coating apparatus (coating step), then transfer the substrate to a thermal treatment apparatus and thermally treat the substrate on which the coating film has been formed in the thermal treatment apparatus (thermal treatment step), then transfer the substrate to a grinding apparatus and grind the coating film on the front surface of the substrate which has been thermally treated in the grinding apparatus (grinding step), then transfer the substrate to a cleaning apparatus and clean the substrate whose coating film has been ground in the cleaning apparatus (cleaning step). Since the film forming treatment can be performed on a substrate basis as described above, the time required for the film forming treatment can be shortened as compared with the conventional film forming treatment on the chip basis. Further, since the coating step, the thermal treatment step, the grinding step, and the cleaning step are performed in one film forming system, a series of film forming treatment can be efficiently performed. Further, the coating step, the thermal treatment step, the grinding step, and the cleaning step can be performed on a plurality of substrates in parallel in this film forming system. Therefore, according to the present invention, the throughput of the film forming treatment can be improved.

Further, in the case of the conventional coating treatment on the chip basis, since the coating film is formed between the chips and the wiring substrate, there is no need to grind the coating film, whereas in the case of the coating treatment on the substrate basis, there is a need to grind the coating film. Here, for the coating treatment on the substrate basis, for example, a so-called spin coating method is used which supplies a coating solution, for example, to the substrate which is being rotated to diffuse and apply the coating solution on the substrate by the centrifugal force. However, to adjust the coating film during the spin coating, a large amount of coating solution needs to be supplied onto the substrate. In this regard, according to the present invention, the grinding of the coating film is performed in the grinding apparatus that is different from the coating apparatus, and therefore it is unnecessary to supply the coating solution in order to adjust the coating film in the coating apparatus, thereby suppressing the supply amount of the coating solution to a small amount. Accordingly, a series of film forming treatment can be efficiently performed.

As described above, according to the present invention, it is possible to efficiently perform film formation of a coating film on a substrate having a plurality of circuits formed on a front surface thereof to improve the throughput of the film forming treatment.

### BRIEF DESCRIPTION OF THE DRAWINGS

FIG. 1 is a plan view illustrating the outline of a configuration of a film forming system according to an embodiment;

FIG. 2 is a side view illustrating the outline of an internal configuration of the film forming system according to this embodiment;

FIG. 3 is a longitudinal sectional view illustrating the outline of a configuration of a first thermal treatment apparatus;

FIG. 4 is a transverse sectional view illustrating the outline of the configuration of the first thermal treatment apparatus;

FIG. 5 is a longitudinal sectional view illustrating the outline of a configuration of a second thermal treatment apparatus;

FIG. 6 is a plan view illustrating the outline of a configuration of a wafer transfer mechanism;

FIG. 7 is a plan view illustrating the outline of a configuration of a hot plate;

FIG. 8 is a cross-sectional view illustrating the outline of the configuration of the hot plate;

FIG. 9 is a longitudinal sectional view illustrating the outline of a configuration of a coating apparatus;

FIG. 10 is a transverse sectional view illustrating the outline of the configuration of the coating apparatus;

FIG. 11 is a perspective view illustrating the outline of a configuration of a coating head;

FIG. 12 is an explanatory view illustrating an appearance of applying a coating solution onto a wafer;

FIG. 13 is a transverse sectional view illustrating the outline of a configuration of a grinding apparatus;

FIG. 14 is a side view illustrating the outline of the configuration of the grinding apparatus;

FIG. 15 is a plan view illustrating the outline of a configuration of a third treatment block;

FIG. 16 is a longitudinal sectional view illustrating the outline of a configuration of a front surface cleaning unit;

FIG. 17 is a transverse sectional view illustrating the outline of the configuration of the front surface cleaning unit;

FIG. 18 is a longitudinal sectional view illustrating the outline of a configuration of a rear surface cleaning unit;

FIG. 19 is a plan view illustrating the outline of a configuration of a spin chuck;

FIG. 20 is a plan view illustrating the outline of a configuration of a first transfer arm;

FIG. 21 is a side view illustrating the outline of the configuration of the first transfer arm; and

FIG. 22 is a flowchart illustrating main steps of a film forming treatment.

### DETAILED DESCRIPTION OF THE INVENTION

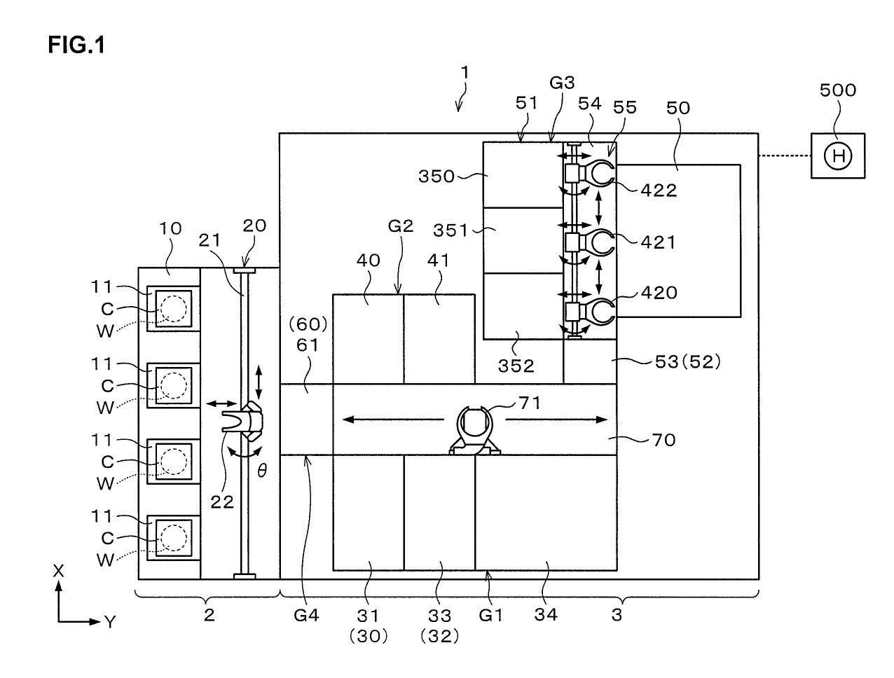

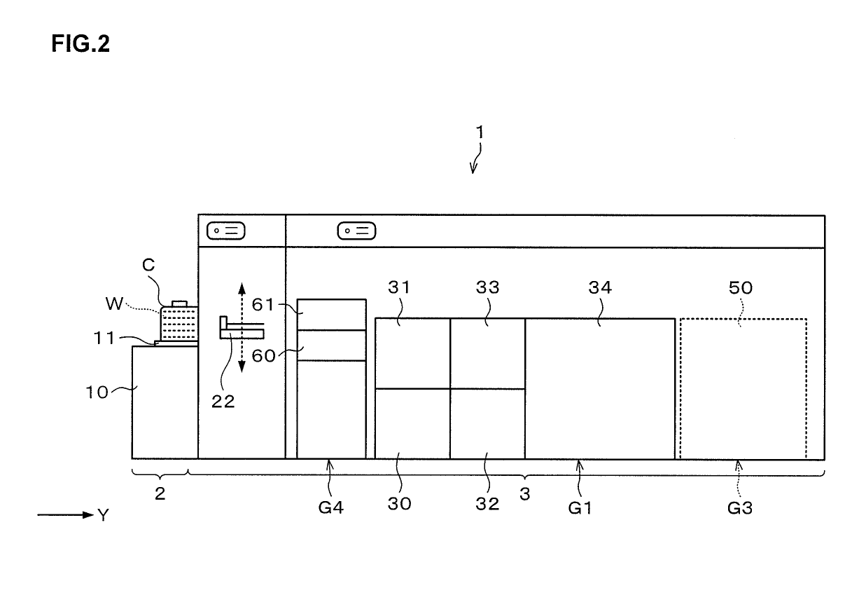

Hereinafter, an embodiment of the present invention will be described. FIG. 1 is a plan view illustrating the outline of a film forming system 1 according to this embodiment. FIG. 2 is a side view illustrating the outline of an internal configuration of the film forming system 1. Note that in this embodiment, a plurality of circuits have been formed on a front surface of a wafer as a substrate to be subjected to film forming treatment in the film forming system 1. Further, a coating film is formed on the wafer to seal the circuits in the film forming system 1.

The film forming system 1 has, as illustrated in FIG. 1, a configuration in which, for example, a transfer-in/out station 2 into which a cassette C capable of housing a plurality of wafers W is transferred in/out from/to, for example, the outside, a treatment station 3 including various kinds of treatment apparatuses that perform predetermined treatments on the wafers W, are integrally connected.

In the transfer-in/out station 2, a cassette mounting table 10 is provided. The cassette mounting table 10 is provided with, a plurality of, for example, four cassette mounting plates 11. The cassette mounting plates 11 are provided, arranged side by side in a line in an X-direction (a top and bottom direction in FIG. 1). On the cassette mounting plates 11, cassettes C can be mounted when the cassettes C are transferred in/out from/to the outside of the film forming system 1. As described above, the transfer-in/out station 2 is configured to be capable of retaining a plurality of wafers W. Note that the number of cassette mounting plates 11 is not limited to that in this embodiment but may be arbitrarily decided.

In the transfer-in/out station 2, a wafer transfer region 20 is provided adjacent to the cassette mounting table 10. In the wafer transfer region 20, a wafer transfer apparatus 22 is provided which is movable on a transfer path 21 extending in the X-direction. The wafer transfer apparatus 22 is movable also in the vertical direction and around a vertical axis (in a θ-direction), and can transfer the wafer W between the cassette C on each of the cassette mounting plates 11 and later-described transition apparatuses 60, 61 in a fourth treatment block G4 in the treatment station 3.

In the treatment station 3, a plurality of, for example, four treatment blocks G1, G2, G3, G4 are provided each including various treatment apparatuses. For example, the first treatment block G1 is provided on the front side (an X-direction negative direction side in FIG. 1) in the treatment station 3, and the second treatment block G2 and the third treatment block G3 are provided on the rear side (an X-direction positive direction side in FIG. 1) in the treatment station 3. The second treatment block G2 and the third treatment block G3 are arranged side by side in the Y-direction in this order from the transfer-in/out station 2 side. Further, the fourth treatment block G4 is provided on the transfer-in/out station 2 side (a Y-direction negative direction side in FIG. 1) in the treatment station 3.

For example, in the first treatment block G1, as illustrated in FIG. 2, first thermal treatment apparatuses 30 to 33 each of which thermally treats the wafer W at a low temperature (a first temperature) and a second thermal treatment apparatus 34 which thermally treats the wafer W at a high temperature (a second temperature higher than the first temperature) are arranged side by side in the Y-direction in this order from the transfer-in/out station 2 side. A stack of the first thermal treatment apparatuses 30, 31 and a stack of the first thermal treatment apparatuses 32, 33 are arranged side by side in this order in the Y-direction from the transfer-in/out station 2 side, and those apparatuses in each stack are provided at two tiers in this order from the bottom in the vertical direction. Note that the number and the arrangement in the vertical direction and the horizontal direction, of the first thermal treatment apparatuses 30 to 33 are not limited to those in this embodiment but can be arbitrarily set.

For example, in the second treatment block G2, as illustrated in FIG. 1, coating apparatuses 40, 41 each of which applies a coating solution onto the wafer W to form a containing film are arranged side by side in the Y-direction in this order from the transfer-in/out station 2 side.

For example, in the third treatment block G3, a grinding apparatus 50 that grinds the coating film on the wafer W, a cleaning apparatus 51 that cleans the wafer W whose coating film has been ground in the grinding apparatus 50, and transition apparatuses 52, 53 for the wafer W are provided. In a region surrounded by the grinding apparatus 50, the cleaning apparatus 51, and the transition apparatuses 52, 53, a wafer transfer region 54 is formed. In the wafer transfer region 54, a wafer transfer apparatus 55 is arranged which transfers the wafer W, for example, to the grinding apparatus 50, the cleaning apparatus 51, and the transition apparatuses 52, 53. The cleaning apparatus 51, the wafer transfer region 54, and the grinding apparatus 50 are arranged side by side in the Y-direction in this order from the transfer-in/out station 2 side. Further, the transition apparatuses 52, 53 are provided on the X-direction negative direction side of the wafer transfer region 54 and provided at two tiers in this order from the bottom.

For example, in the fourth treatment block G4, the transition apparatuses 60, 61 for the wafer W are provided at two tiers in this order from the bottom.

In a region surrounded by the first treatment block G1 to the fourth treatment block G4, a wafer transfer region 70 is formed. In the wafer transfer region 70, for example, a wafer transfer apparatus 71 is arranged.

The wafer transfer apparatus 71 has a transfer arm that is movable, for example, in the vertical direction and the horizontal directions (the Y-direction, the X-direction) and around the vertical axis. The wafer transfer apparatus 71 can move in the wafer transfer region 70 to transfer the wafer W to a predetermined apparatus in the first treatment block G1, the second treatment block G2, the third treatment block G3 and the fourth treatment block G4 therearound.

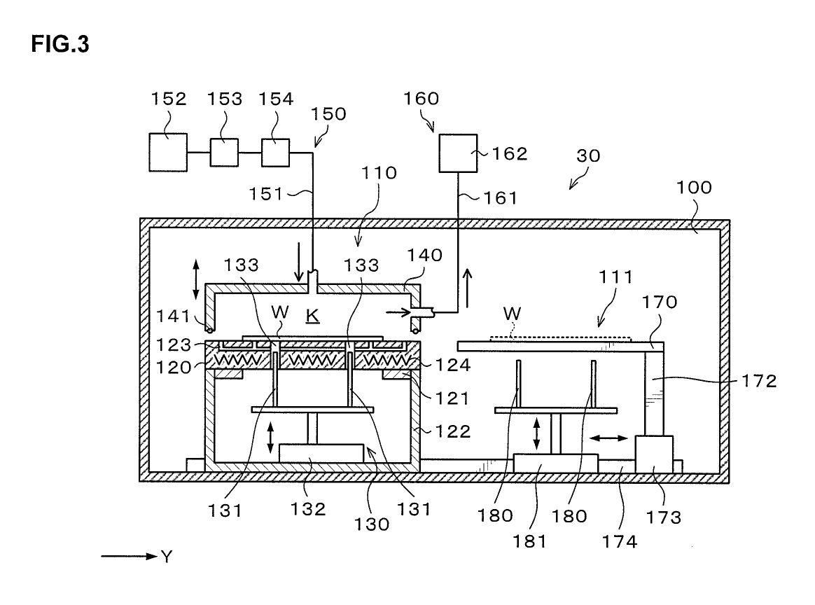

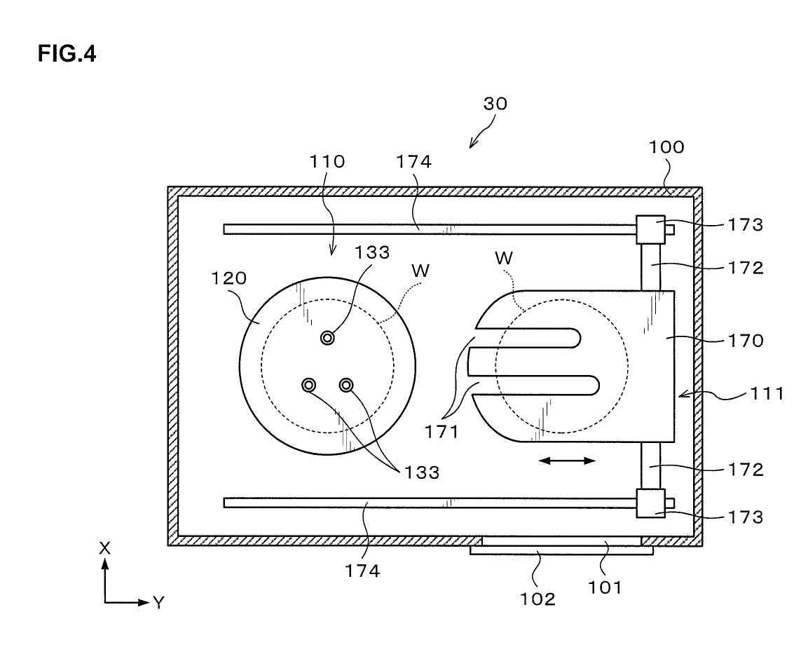

Next, the configurations of the first thermal treatment apparatuses 30 to 33 in the above-descried first treatment block G1 will be described. The first thermal treatment apparatus 30 has a treatment container 100 as a first treatment container that can hermetically close the inside thereof as illustrated in FIG. 3. A transfer-in/out port 101 for the wafer W is formed as illustrated in FIG. 4 in a side surface on the wafer transfer region 70 side of the treatment container 100, and an opening/closing shutter 102 is provided at the transfer-in/out port 101.

Inside the treatment container 100, a heating section 110 that heat-treats the wafer W and a temperature regulation section 111 that temperature-regulates the wafer W are provided as illustrated in FIG. 3 and FIG. 4. The heating section 110 and the temperature regulation section 111 are arranged side by side in the Y-direction.

The heating section 110 includes an annular holding member 121 that accommodates a hot plate 120 as a first thermal treatment plate and holds the outer peripheral portion of the hot plate 120, and a cylindrical support ring 122 that surrounds the outer periphery of the holding member 121. The hot plate 120 has an almost disk shape with a large thickness. Inside the hot plate 120, a suction pipe 123 for suction-holding the wafer W is provided. The suction pipe 123 is connected to a negative pressure generating device (not illustrated) such as, for example, a vacuum pump. Thus, the wafer W is sucked from the suction pipe 123 so that the wafer W is suction-held on the hot plate 120. For example, even if the wafer W is warped, the wafer W is properly suction-held by the suction force from the suction pipe 123. Further, for example, a heater 124 is embedded inside the hot plate 120. The heating temperature of the hot plate 120 is controlled, for example, by a control unit 500 so that the wafer W mounted on the hot plate 120 is heated to a predetermined first temperature, for example, 120° C. to 150° C.

Below the hot plate 120, a raising and lowering mechanism 130 is provided which raises and lowers the wafer W. The raising and lowering mechanism 130 has, for example, three raising and lowering pins 131 for supporting the wafer W from below and raising and lowering the wafer W. The raising and lowering pins 130 can rise and lower by means of a raising and lowering drive part 132. Near the middle portion of the hot plate 120, through holes 133 penetrating the hot plate 120 in the thickness direction thereof are formed, for example, at three positions. The raising and lowering pins 131 are inserted into the through holes 133 to be able to project from the upper surface of the hot plate 120.

Above the hot plate 120, a lid body 140 is provided which freely rises and lowers. The lid body 140 has a lower surface open and forms a thermal treatment chamber K together with the hot plate 120. Further, on the lower surface of the lid body 140, a sealing material 141 is annularly provided. Thus, when the thermal treatment chamber K is formed by the hot plate 120 and the lid body 140, the air tightness of the inside of the thermal treatment chamber K is maintained by the sealing material 141 provided between the upper surface of the hot plate 120 and the lower surface of the lid body 140.

The lid body 140 is provided with a gas supply mechanism 150 that supplies an inert gas such as a nitrogen gas into the thermal treatment chamber K. The gas supply mechanism 150 has a gas supply pipe 151 that is connected to the central portion of a ceiling surface of the lid body 140 and supplies the inert gas into the thermal treatment chamber K. The gas supply pipe 151 communicates with a gas supply source 152 that stores the inert gas therein. Further, the gas supply pipe 151 is provided with a supply equipment group 153 including a valve, a flow regulator and so on that control the flow of the inert gas. The gas supply pipe 151 is further provided with a heater 154 that heats the inert gas to be supplied to the thermal treatment chamber K to a predetermined temperature, for example, 120° C. to 150° C. Note that the heating of the inert gas in the thermal treatment chamber K is not limited to that in this embodiment, but the inert gas may be heated utilizing the heat of the hot plate 120 or may be heated by a heating mechanism (not illustrated) provided inside the lid body 140.

The lid body 140 is further provided with a pressure reducing mechanism 160 that reduces the pressure of the atmosphere in the thermal treatment chamber K down to a predetermined degree of vacuum, for example, 20 kPa. The pressure reducing mechanism 160 has an intake pipe 161 that is connected to the side surface of the lid body 140 and vacuums the thermal treatment chamber K to reduce the pressure therein. The intake pipe 161 communicates with a negative pressure generating device 162 such as, for example, a vacuum pump.

The temperature regulation section 111 has a temperature regulation plate 170. The temperature regulation plate 170 has an almost square flat plate shape as illustrated in FIG. 4 and has an end face on the hot plate 120 side curved in an arc shape. In the temperature regulation plate 170, two slits 171 are formed along the Y-direction. The slits 171 are formed from the end face on the hot plate 120 side of the temperature regulation plate 170 to the vicinity of the middle portion of the temperature regulation plate 170. The slits 171 can prevent the temperature regulation plate 170 from interfering with the raising and lowering pins 131 of the heating section 110 and later-described raising and lowering pins 180 of the temperature regulation section 111. Further, in the temperature regulation plate 170, a temperature regulation member (not illustrated) such as a Peltier element is embedded. The cooling temperature of the temperature regulation plate 170 is controlled, for example, by the control unit 500 so that the wafer W mounted on the temperature regulation plate 170 is cooled to a predetermined temperature, for example, 50° C.

The temperature regulation plate 170 is supported on a supporting arm 172 as illustrated in FIG. 3. To the supporting arm 172, a drive part 173 is attached. The drive part 173 is attached on a rail 174 extending in the Y-direction. The rail 174 extends from the temperature regulation section 111 to the heating section 110. By means of the drive part 173, the temperature regulation plate 170 can move along the rail 174 between the heating section 110 and the temperature regulation section 111.

Below the temperature regulation plate 170, for example, three raising and lowering pins 180 for supporting the wafer W from below and raising and lowering it are provided. The raising and lowering pins 180 can rise and lower by means of a raising and lowering drive part 181. Further, the raising and lowering pins 180 are inserted into the slits 171 to be able to project from the upper surface of the temperature regulation plate 170.

Note that the configurations of the first thermal treatment apparatuses 31 to 33 are the same as that of the above-described first thermal treatment apparatus 30, and therefore the description thereof is omitted.

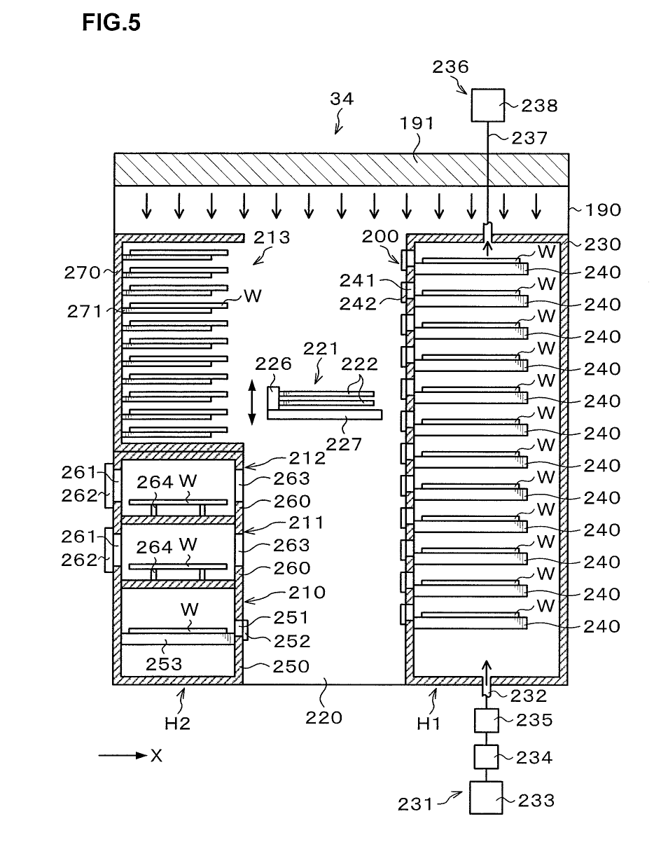

Next, the configuration of the second thermal treatment apparatus 34 in the above-descried first treatment block G1 will be described. The second thermal treatment apparatus 34 has a housing 190 as illustrated in FIG. 5. At the ceiling surface of the housing 190, a fan filter unit 191 (FFU) is provided. By the fan filter unit 191, a down flow is formed inside the housing 190.

In the housing 190, two treatment blocks H1, H2 are provided each of which includes various treatment units. For example, the first treatment block H1 is provided on an X-direction positive direction side in the housing 190, and the second treatment block H2 is provided on an X-direction negative direction side in the housing 190, namely, on the wafer transfer region 70 side.

For example, in the first treatment block H1, a thermal treatment unit 200 is provided which houses and thermally treats a plurality of wafers W therein.

For example, in the second treatment block H2, a temperature regulation unit 210 that regulates the thermally treated wafer W to a predetermined temperature, transition units 211, 212 for transferring in/out the wafer W from/to the outside, and a buffer unit 213 that temporarily houses a plurality of wafers W, are provided at four tiers in this order from the bottom.

Between the first treatment block H1 and the second treatment block H2, a wafer transfer region 220 is formed. In the wafer transfer region 220, a wafer transfer mechanism 221 is provided which transfers the wafer W to a predetermined unit in the first treatment block H1 and the second treatment block H2.

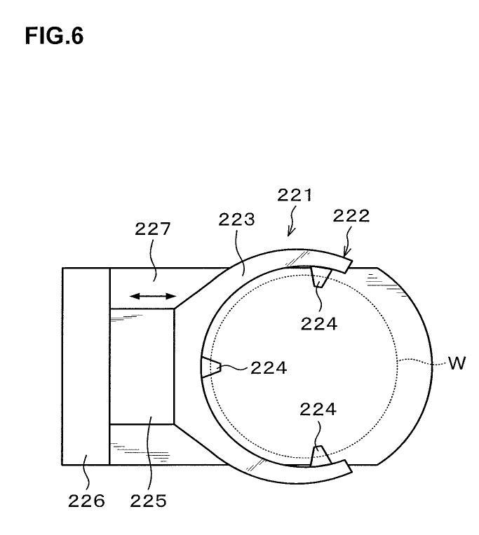

The wafer transfer mechanism 221 has a plurality of, for example, two transfer arms 222. The transfer arm 222 has an arm part 223 that is configured in an almost C-shape as illustrated in FIG. 6. The arm part 223 is curved along the peripheral edge portion of the wafer W with a radius of curvature larger than the radius of the wafer W. The arm part 223 is provided with holding parts 224 that project inward from the arm part 223 and hold the outer peripheral portion of the rear surface of the wafer W at a plurality of, for example, three positions. The transfer arm 222 can thus horizontally hold the wafer W on the holding parts 224.

At the base end portion of the arm part 223, a support part 225 is provided which is integrally formed with the arm part 223 and supports the arm part 223. The support part 225 is provided with an arm drive part (not illustrated).

Further, at the base end portions of the transfer arms 222, an arm drive part 226 is provided. By means of the arm drive part 226, each of the transfer arms 222 can independently move in the horizontal direction. The transfer arms 222 and the arm drive part 226 are supported on a base 227. The base 227 is provided with a moving mechanism (not illustrated), and the wafer transfer mechanism 221 is configured to freely rise and lower and rotatable around the vertical axis by means of the moving mechanism.

Next, the configuration of the thermal treatment unit 200 will be described. The thermal treatment unit 200 has a treatment container 230 as a second treatment container that can hermetically close the inside thereof as illustrated in FIG. 5.

The treatment container 230 is provided with a gas supply mechanism 231 that supplies an inert gas, for example, a nitrogen gas into the treatment container 230. The gas supply mechanism 231 has a gas supply pipe 232 that is connected to the bottom surface of the treatment container 230 and supplies the inert gas into the treatment container 230. The gas supply pipe 232 communicates with a gas supply source 232 that stores the inert gas therein. Further, the gas supply pipe 232 is provided with a supply equipment group 234 including a valve, a flow regulator and so on that control the flow of the inert gas. The gas supply pipe 232 is further provided with a heater 235 as a heating mechanism that heats the inert gas to be supplied to the treatment container 230 to a predetermined temperature. Note that the inert gas may be supplied, for example, at 23° C. being room temperature or may be heated to a temperature higher than room temperature by the heater 235 and then supplied. Further, the heating of the inert gas in the treatment container 230 is not limited to that in this embodiment, but the inert gas may be heated utilizing the heat of a later-described hot plate 240 or may be heated by a heating mechanism (not illustrated) provided inside the treatment container 230.

The treatment container 230 is further provided with an exhaust mechanism 236 that exhausts the atmosphere in the treatment container 230. The exhaust mechanism 236 has an exhaust pipe 237 that is connected to a ceiling surface of the treatment container 230 and exhausts gas in the treatment container 230 by vacuuming. The exhaust pipe 237 communicates with a negative pressure generating device 238 such as, for example, a vacuum pump.

Inside the treatment container 230, a hot plate 240 as a second thermal treatment plate is provided which mounts and thermally treats the wafer W thereon. The hot plate 240 is provided at each of a plurality of tiers, for example, 12 tiers in the vertical direction. Opposite the hot plates 240, transfer-in/out ports 241 for the wafer W are formed respectively in the side surface of the treatment container 230 on the wafer transfer region 220 side, and opening/closing shutters 242 are provided respectively at the respective transfer-in/out ports 241. Note that the number of hot plates 240 is not limited to that in this embodiment but may be arbitrarily set.

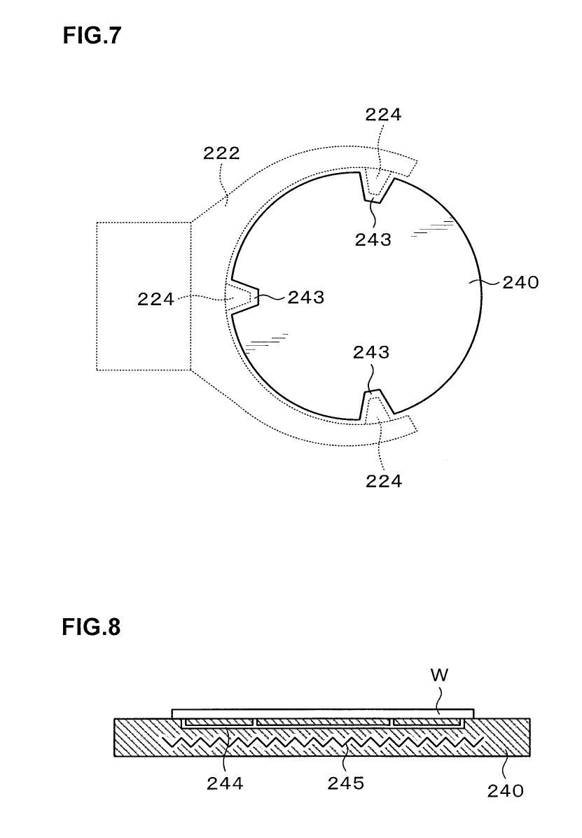

The hot plate 240 has an almost disk shape with a large thickness as illustrated in FIG. 7. At the outer peripheral portion of the hot plate 240, cutouts 243 are provided at, for example, three positions. The cutouts 243 make it possible to prevent the holding parts 224 of the transfer arm 222 of the wafer transfer mechanism 221 from interfering with the hot plate 240 when the wafer W is delivered between the hot plate 240 and the wafer transfer mechanism 221.

Inside the hot plate 240, a suction pipe 244 for suction-holding the wafer W is provided as illustrated in FIG. 8. The suction pipe 244 is connected to a negative pressure generating device (not illustrated) such as, for example, a vacuum pump. Thus, the wafer W is sucked from the suction pipe 244 so that the wafer W is suction-held on the hot plate 240. For example, even if the wafer W is warped, the wafer W is properly suction-held by the suction force from the suction pipe 244. Further, for example, a heater 245 is embedded in the hot plate 240. The heating temperature of the hot plate 240 is controlled, for example, by the control unit 500 so that the wafer W mounted on the hot plate 240 is heated to a predetermined second temperature, for example, 150° C. to 250° C.

Next, the configuration of the temperature regulation unit 210 will be described. The temperature regulation unit 210 has a treatment container 250 that can hermetically close the inside thereof as illustrated in FIG. 5. A transfer-in/out port 251 for the wafer W is formed in a side surface on the wafer transfer region 220 side of the treatment container 250, and an opening/closing shutter 252 is provided at the transfer-in/out port 251.

Inside the treatment container 250, a temperature regulation plate 253 is provided which temperature-regulates the wafer W thermally treated on the hot plate 240. The temperature regulation plate 253 has an almost disk shape similarly to the hot plate 240, and cutouts (not illustrated) similar to the cutouts 243 are formed at the outer peripheral portion of the temperature regulation plate 253. Further, in the temperature regulation plate 253, a temperature regulation member (not illustrated) such as a Peltier element is embedded. The cooling temperature of the temperature regulation plate 253 is controlled, for example, by the control unit 500 so that the wafer W mounted on the temperature regulation plate 253 is cooled to a predetermined temperature, for example, 23° C. being room temperature. Note the number of the temperature regulation plates 253 is not limited to that in this embodiment but can be arbitrarily set.

Next, the configuration of the transition units 211, 212 will be described. The transition unit 211 has a treatment container 260 that can house the wafer W. A transfer-in/out port 261 for the wafer W is formed in a side surface on the wafer transfer region 70 side of the treatment container 260, and an opening/closing shutter 262 is provided at the transfer-in/out port 261. Further, a transfer-in/out port 263 for the wafer W is formed in a side surface on the wafer transfer region 220 side of the treatment container 260. In the treatment container 260, support pins 264 that support the wafer W are provided. With the above configuration, the treatment container 260 can temporarily house the wafer W. Note that the configuration of the transition unit 212 is the same as that of the transition unit 211, and therefore the description thereof is omitted.

Next, the configuration of the buffer unit 213 will be described. The buffer unit 213 has a treatment container 270 with a side surface on the wafer transfer region 220 side open. Inside the treatment container 270, a holding member 271 that holds the wafer W is provided. The holding member 271 is provided at each of a plurality of tiers, for example, 12 tiers in the vertical direction. With the above configuration, the buffer unit 213 can temporarily house a plurality of wafers W.

The buffer unit 213 is used, for example, for suspending the thermal treatment for a plurality of wafers W at the middle, in the thermal treatment unit 200. For example, when failure occurs in an apparatus other than the second thermal treatment apparatus 34 in the film forming system 1, a series of film forming treatment is suspended in some case. In this case, the plurality of wafers W in the thermal treatment unit 200 are transferred from the treatment container 230 to the buffer unit 213 and temporarily housed in the buffer unit 213. This can prevent, for example, overheating of the wafers W by the hot plates 240 in the thermal treatment unit 200.

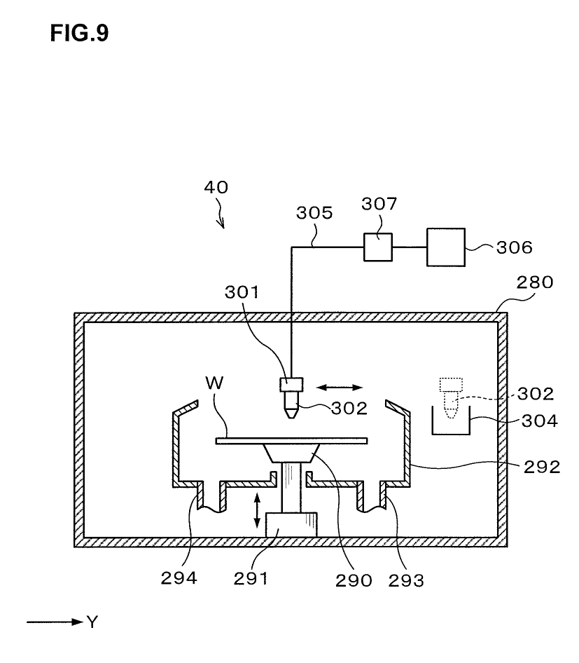

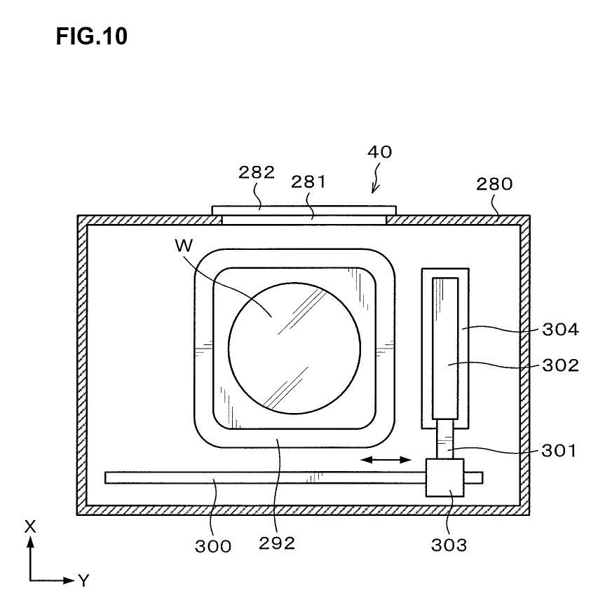

Next, the configurations of the above-described coating apparatuses 40, 41 in the second treatment block G2 will be described. The coating apparatus 40 has a treatment container 280 that can hermetically close the inside thereof as illustrated in FIG. 9. A transfer-in/out port 281 for the wafer W is formed as illustrated in FIG. 10 in a side surface on the wafer transfer region 70 side of the treatment container 280, and an opening/closing shutter 282 is provided at the transfer-in/out port 281.

At a central portion in the treatment container 280, a chuck 290 that holds the wafer W is provided as illustrated in FIG. 9. The chuck 290 has a horizontal upper surface and, for example, a suction port (not illustrated) that sucks the wafer W is provided in the upper surface. By suction through the suction port, the wafer W can be suction-held on the chuck 290.

Below the chuck 290, a chuck drive part 291 is provided. The chuck drive part 291 is provided with, for example, a raising and lowering drive source such as a cylinder so that the chuck 290 can freely rise and lower.

Around the chuck 290, a cup 292 is provided which receives and recovers liquid dropping from the wafer W. A drain pipe 293 that drains the recovered liquid and an exhaust pipe 294 that exhausts the atmosphere in the cup 292 by vacuuming are connected to the lower surface of the cup 292.

As illustrated in FIG. 10, on an X-direction negative direction (a downward direction in FIG. 10) side of the cup 292, a rail 300 extending along a Y-direction (a right-left direction in FIG. 10) is formed. The rail 300 is formed, for example, from a Y-direction negative direction (a left direction in FIG. 10) side outer position of the cup 292 to a Y-direction positive direction (a right direction in FIG. 10) side outer position. On the rail 300, an arm 301 is attached.

On the arm 301, a coating head 302 that supplies a liquid coating solution to the wafer W is supported as illustrated in FIG. 9 and FIG. 10. The arm 301 is movable on the rail 300 by means of a head drive part 303 illustrated in FIG. 10. Thus, the coating head 302 can move from a waiting section 304 provided at a Y-direction positive direction side outer position of the cup 292 to a position above a central portion of the wafer W in the cup 292, and further move in the radial direction of the wafer W above the wafer W. Further, the arm 301 can freely rise and lower by means of the head drive part 303 to be able to adjust the height of the coating head 302. Note that the rail 300, the arm 301, and the head drive part 303 constitute a moving mechanism of the present invention in this embodiment.

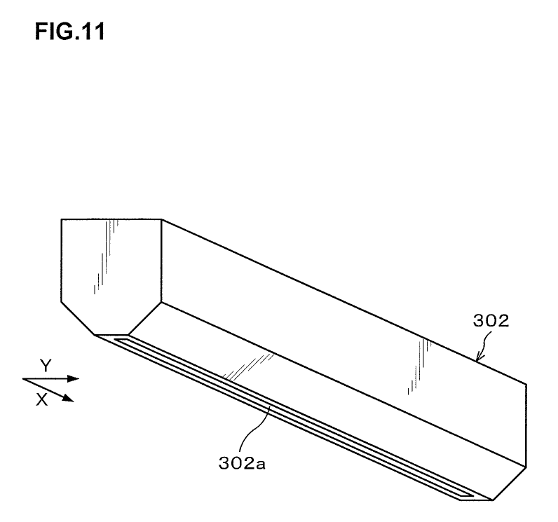

The coating head 302 is formed in an almost parallelepiped shape extending in the X-direction as illustrated in FIG. 11. The coating head 302 is formed, for example, longer than the diameter of the wafer W. At the lower end portion of the coating head 302, a discharge port 302a in a slit form for the coating solution is formed.

To the coating head 302, a supply pipe 305 is connected which supplies the coating solution to the coating head 302 as illustrated in FIG. 9. The supply pipe 305 communicates with a coating solution supply source 306 that stores the coating solution therein. Further, the supply pipe 305 is provided with a supply equipment group 307 including a valve, a flow regulator and so on that control the flow of the coating solution.

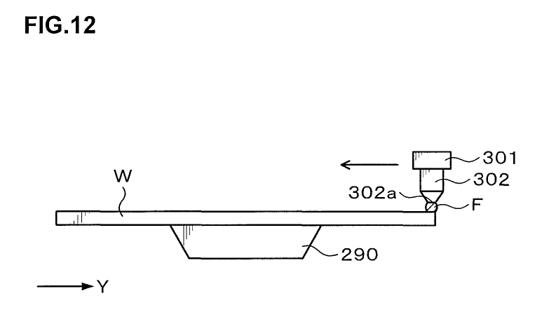

Then, in the coating apparatus 40, the coating head 302 is moved in the radial direction of the wafer W (a Y-direction negative direction side in the example in FIG. 12) with a coating solution F exposed by the surface tension from the discharge port 302a of the coating head 302 kept in contact with the front surface of the wafer W as illustrated in FIG. 12. Thus, the coating solution F exposed from the discharge port 302a is sequentially supplied by the action of the surface tension, whereby the coating solution F is applied over the entire surface of the wafer W.

Note that the configuration of the coating apparatus 41 is the same as that of the above-described coating apparatus 40, and therefore the description thereof is omitted.

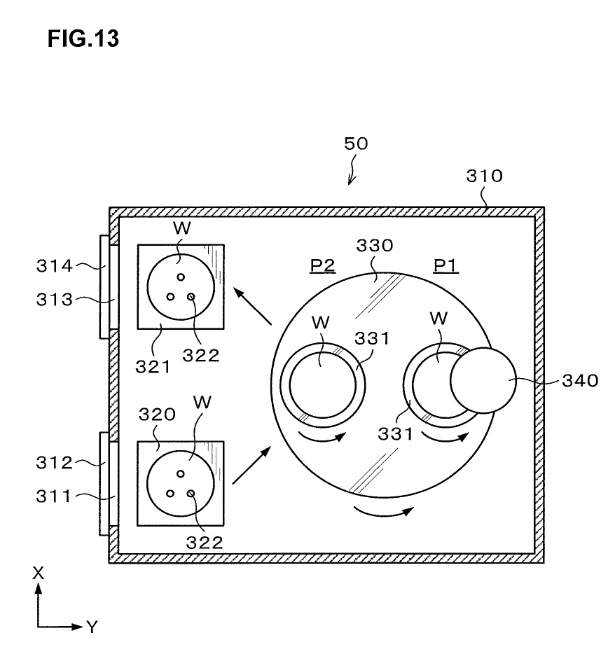

Next, the configuration of the above-described grinding apparatus 50 in the third treatment block G3 will be described. The grinding apparatus 50 has a treatment container 310 that can hermetically close the inside thereof as illustrated in FIG. 13. A transfer-in/out port 311 for the wafer W is formed at a position facing a later-described transfer-in section 320 in a side surface on the wafer transfer region 54 side of the treatment container 310, and an opening/closing shutter 312 is provided at the transfer-in/out port 311. Further, a transfer-in/out port 313 for the wafer W is formed at a position facing a later-described transfer-out section 321 in the side surface on the wafer transfer region 54 side of the treatment container 310, and an opening/closing shutter 314 is provided at the transfer-in/out port 313.

Inside the treatment container 310, the transfer-in section 320 that temporarily mounts the wafer W transferred from the outside into the treatment container 310 thereon, and the transfer-out section 321 that temporarily mounts the wafer W to be transferred out of the treatment container 310 to the outside thereon are provided. The transfer-in section 320 and the transfer-out section 321 are arranged side by side in this order in the X-direction positive direction. Each of the transfer-in section 320 and the transfer-out section 321 is provided with support pins 322 that support the wafer W.

Inside the treatment container 310, a stage 330 is further provided which mounts the wafer W thereon and grinds the coating film F on the wafer W. The stage 330 is provided on the Y-direction positive direction side of the transfer-in section 320 and the transfer-out section 321. Further, the stage 330 is configured to be rotatable by a rotary mechanism (not illustrated).

On the stage 330, two chucks 331, 331 are provided each of which suction-holds the wafer W. The chucks 331, 331 are arranged, for example, at positions facing each other across the center point of the stage 330. Further, the chucks 331, 331 are configured to be rotatable by means of rotary mechanisms (not illustrated). By rotating the stage 330, the chucks 331, 331 can move between a treatment position P1 where the coating film F on the wafer W is ground and a waiting position P2 where the wafer W is kept waiting.

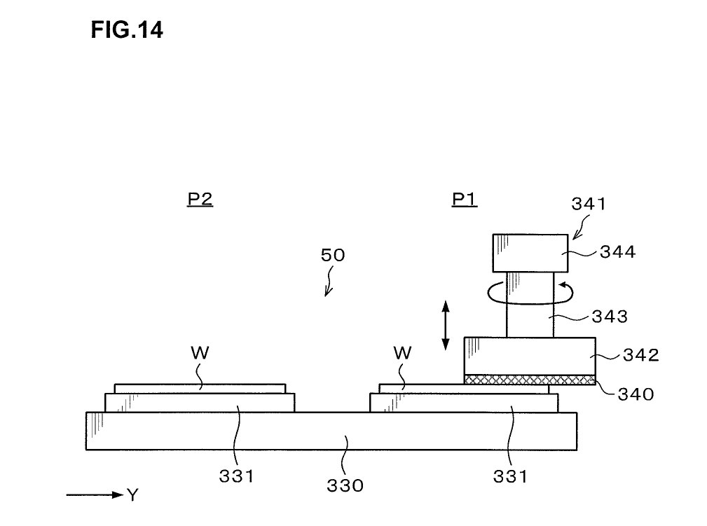

At the treatment position P1 and above the chuck 331, a grinding mechanism 340 that polishes and grinds the coating film F on the wafer W is provided as illustrated in FIG. 14. The grinding mechanism 340 functions as a polishing mechanism for which, for example, a grinding wheel is used.

The grinding mechanism 340 is provided with a rotary mechanism 341 that rotates the grinding mechanism 340. The rotary mechanism 341 has a rotary plate 342 that supports the grinding mechanism 340, a spindle 343 that is provided at the rotary plate 342, and a drive part 344 that rotates the rotary plate 342 via the spindle 343. The chuck 331 and the grinding mechanism 340 are individually rotated with the wafer W held on the chuck 331 kept in contact with the grinding mechanism 340, thereby grinding the coating film F on the wafer W.

Note that in the treatment container 310 of the grinding apparatus 50, a wafer transfer mechanism (not illustrated) is provided which transfers the wafer W between the transfer-in section 320, the transfer-out section 321, and the stage 330.

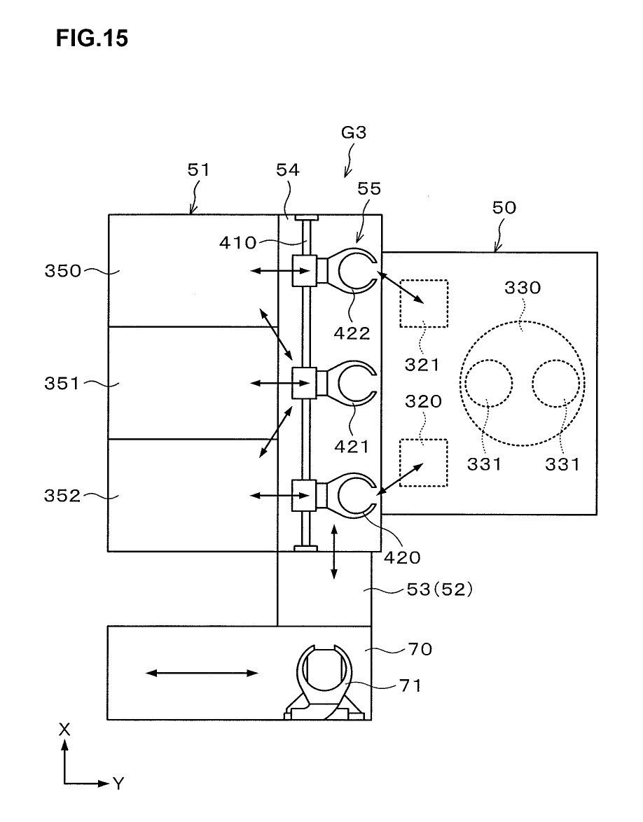

Next, the configuration of the above-described cleaning apparatus 51 in the third treatment block G3 will be described. The cleaning apparatus 51 has, as illustrated in FIG. 15, a front surface cleaning unit 350 that cleans the front surface of the wafer W, a rear surface cleaning unit 351 that cleans the rear surface of the wafer W, a finish cleaning unit 352 that cleans the front surface of the wafer W which has been subjected to the cleaning of the front surface of the wafer W in the front surface cleaning unit 350 and subjected to the cleaning of the rear surface of the wafer W in the rear surface cleaning unit 351. The front surface cleaning unit 350, the rear surface cleaning unit 351, and the finish cleaning unit 352 are arranged side by side in this order in an X-direction negative direction.

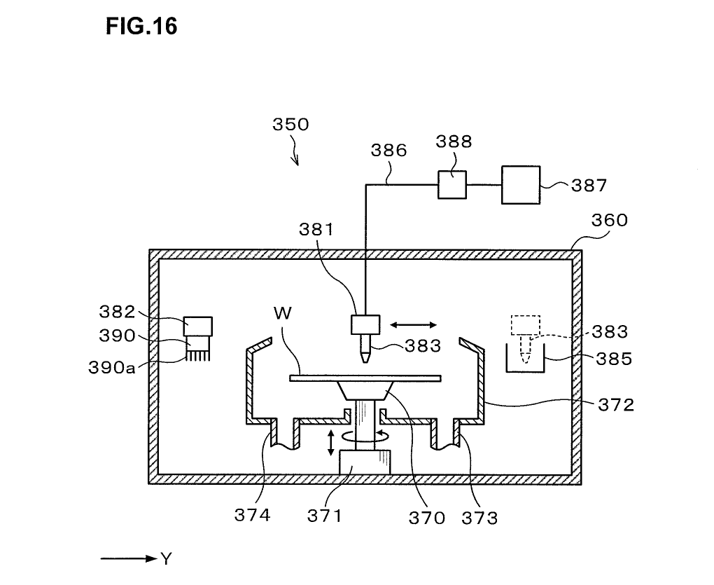

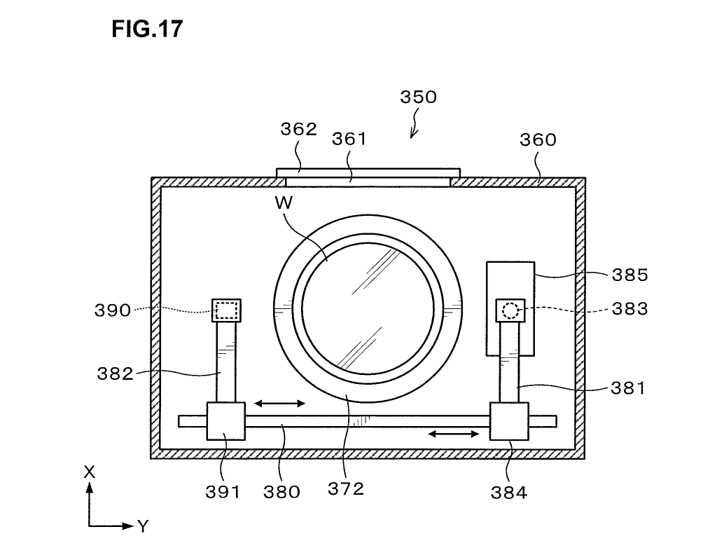

The front surface cleaning unit 350 has a treatment container 360 that can hermetically close the inside thereof as illustrated in FIG. 16. A transfer-in/out port 361 for the wafer W is formed as illustrated in FIG. 17 in a side surface on the wafer transfer region 54 side of the treatment container 360, and an opening/closing shutter 362 is provided at the transfer-in/out port 361.

At a central portion in the treatment container 360, a spin chuck 370 is provided which holds and rotates the wafer W thereon as illustrated in FIG. 16. The spin chuck 370 has a horizontal upper surface, and a suction port (not illustrated) that sucks, for example, the wafer W is provided in the upper surface. By suction through the suction port, the wafer W can be suction-held on the spin chuck 370.

The spin chuck 370 has a chuck drive part 371 and can rotate at a predetermined speed by means of the chuck drive part 371. Further, the chuck drive part 371 is provided with a raising and lowering drive source such as, for example, a cylinder so that spin chuck 370 can freely rise and lower.

Around the spin chuck 370, a cup 372 is provided which receives and recovers liquid splashing or dropping from the wafer W. A drain pipe 373 that drains the recovered liquid and an exhaust pipe 374 that exhausts the atmosphere in the cup 372 by vacuuming are connected to the lower surface of the cup 372.

As illustrated in FIG. 17, on an X-direction negative direction (a downward direction in FIG. 17) side of the cup 372, a rail 380 extending along a Y-direction (a right-left direction in FIG. 17) is formed. The rail 380 is formed, for example, from a Y-direction negative direction (a left direction in FIG. 17) side outer position of the cup 372 to a Y-direction positive direction (a right direction in FIG. 17) side outer position. On the rail 380, for example, a nozzle arm 381 and a scrub arm 382 are attached.

Further, on the nozzle arm 381, a pure water nozzle 383 is supported which supplies pure water at a high pressure to the wafer W as illustrated in FIG. 16 and FIG. 17. The nozzle arm 381 is freely movable on the rail 380 by means of a nozzle drive part 384 illustrated in FIG. 17. Thus, the pure water nozzle 383 can move from a waiting section 385 provided at a Y-direction positive direction side outer position of the cup 372 to a position above a central portion of the wafer W in the cup 372 and further move in the radial direction of the wafer W above the wafer W. Further, the nozzle arm 381 can freely rise and lower by means of the nozzle drive part 384 to be able to adjust the height of the pure water nozzle 383.

To the pure water nozzle 383, a supply pipe 386 is connected which supplies the pure water at a high pressure to the pure water nozzle 383 as illustrated in FIG. 16. The supply pipe 386 communicates with a pure water supply source 387 that stores the pure water therein. Further, the supply pipe 386 is provided with a supply equipment group 388 including a valve, a flow regulator and so on that control the flow of the pure water.

On the scrub arm 382, a scrub cleaning tool 390 is supported. At the tip of the scrub cleaning tool 390, a brush 390a in the shape of plurality threads or sponge is provided. The scrub arm 382 is freely movable on the rail 380 by means of a cleaning tool drive part 391 illustrated in FIG. 17, and can move the scrub cleaning tool 390 from a Y-direction negative direction side outer position of the cup 372 to a position above a central portion of the wafer W in the cup 372. Further, the scrub arm 382 can freely rise and lower by means of the cleaning tool drive part 391 to be able to adjust the height of the scrub cleaning tool 390.

Note that the pure water nozzle 383 and the scrub cleaning tool 390 are supported on separate arms in the above configuration, but may be supported on the same arm. Further, the pure water nozzle 383 may be omitted, and pure water may be supplied from the scrub cleaning tool 390.

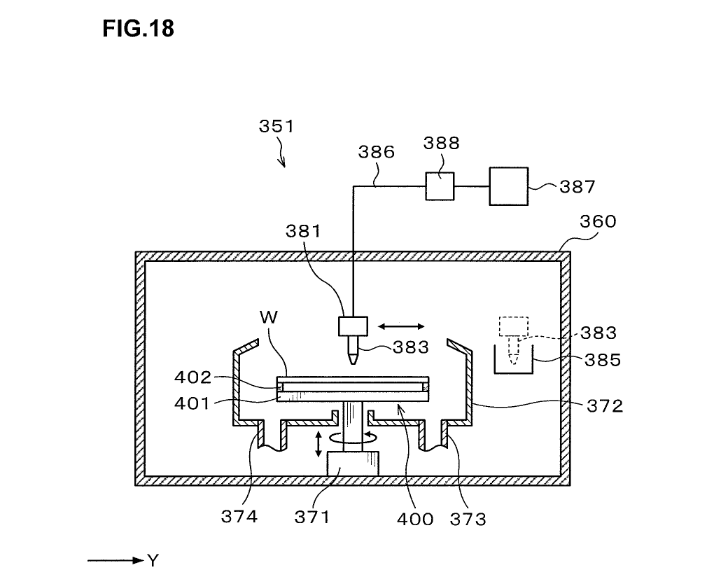

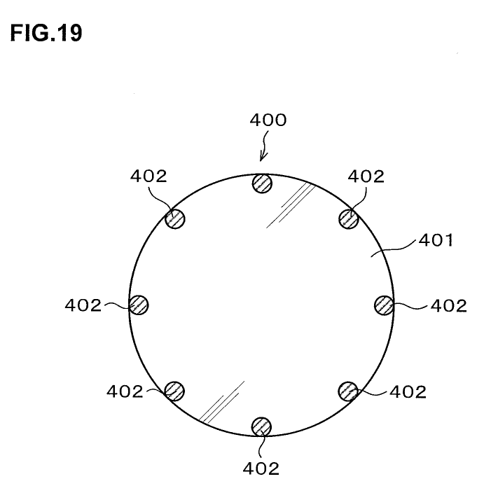

The rear surface cleaning unit 351 has substantially the same configuration of the front surface cleaning unit 350. The rear surface cleaning unit 351 has a spin chuck 400 that holds the outer peripheral portion of the front surface of the wafer W in place of the spin chuck 370 in the front surface cleaning unit 350 as illustrated in FIG. 18. The spin chuck 400 has a main body part 401 in an almost disk shape and holding parts 402 that suction-hold the outer peripheral portion of the front surface of the wafer W as illustrated in FIG. 19. A plurality of holding parts 402 are provided at regular intervals at the outer peripheral portion of the upper surface of the main body part 401. Since the plurality of holding parts 402 suction-hold the outer peripheral portion of the front surface of the wafer W as described above, the circuits formed on the front surface of the wafer W are never damaged. Further, in the rear surface cleaning unit 351, the scrub arm 382, the scrub cleaning tool 390, and the cleaning tool drive part 391 of the front surface cleaning unit 350 are omitted. The other configuration of the rear surface cleaning unit 351 is the same as that of the above-described front surface cleaning unit 350, and therefore the description thereof is omitted.

The finish cleaning unit 352 also has almost the same configuration as that of the above-described front surface cleaning unit 350. In the finish cleaning unit 352, the scrub arm 382, the scrub cleaning tool 390, and the cleaning tool drive part 391 of the front surface cleaning unit 350 are omitted. Further, the pure water to be supplied from the pure water nozzle 383 of the finish cleaning unit 352 does not need to be at a high pressure. The other configuration of the finish cleaning unit 352 is the same as that of the above-described front surface cleaning unit 350, and therefore the description thereof is omitted.

Next, the configurations of the above-described wafer transfer region 54 and wafer transfer apparatus 55 in the third treatment block G3 will be described. In the wafer transfer region 54, a transfer path 410 extending in the X-direction is provided as illustrated in FIG. 15. The wafer transfer apparatus 55 has three transfer arms 420, 421, 422. The transfer arms 420, 421, 422 are arranged side by side in this order toward the X-direction positive direction, and are independently movable on the transfer path 410.

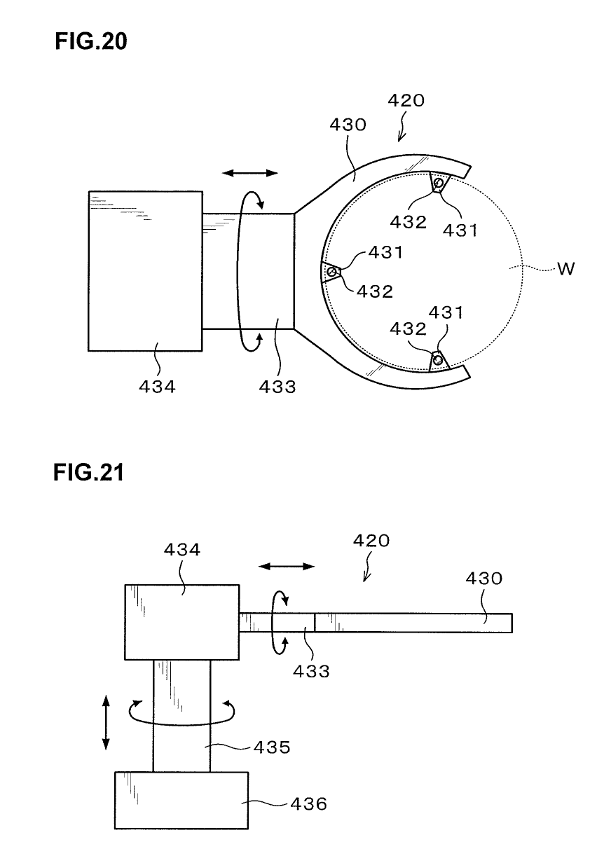

The first transfer arm 420 has an arm part 430 that is configured in an almost C-shape as illustrated in FIG. 20. The arm part 430 is curved along the peripheral edge portion of the wafer W with a radius of curvature larger than the radius of the wafer W. The arm part 430 is provided with holding parts 431 that project inward from the arm part 430 and hold the outer peripheral portion of the wafer W at a plurality of, for example, three positions. At tip portions of the holding parts 431, suction pads 432 are provided. By means of the suction pads 432, the holding parts 431 suck and hold the outer peripheral portion of the wafer W. The first transfer arm 420 can further horizontally hold the wafer W on the holding parts 431.

At the base end portion of the arm part 430, a support part 433 is provided which is integrally formed with the arm part 430 and supports the arm part 430. The support part 433 is supported on a first drive part 434. By means of the first drive part 434, the support part 433 can freely turn around the horizontal axis and expand and contract in the horizontal direction. Namely, the first drive part 434 functions as a reversing mechanism that reverses the front and rear surfaces of the wafer W. Below the first drive part 434, a second drive part 436 is provided via a shaft 435 as illustrated in FIG. 21. By means of the second drive part 436, the first drive part 434 is freely rotatable around the vertical axis and can rise and lower in the vertical direction. Note that the second drive part 436 is attached to the above-described transfer path 410 so that the first transfer arm 420 is freely movable on the transfer path 410.

Note that the configurations of the second transfer arm 421 and the third transfer arm 422 are the same as that of the above-described first transfer arm 420, and therefore the description thereof is omitted.

The first transfer arm 420 transfers the wafer W before the coating film F is ground, between the transition apparatuses 52, 53 and the transfer-in section 320 of the grinding apparatus 50 as illustrated in FIG. 15. Further, the first transfer arm 420 transfers the wafer W after the cleaning, between the finish cleaning unit 352 and the transition apparatuses 52, 53. Namely, the first transfer arm 420 is a transfer arm dedicated to a clean wafer W.

The second transfer arm 421 transfers the wafer W whose front surface has been cleaned, between the front surface cleaning unit 350 and the rear surface cleaning unit 351 of the cleaning apparatus 51. Further, the second transfer arm 421 transfers the wafer W whose rear surface has been cleaned, between the rear surface cleaning unit 351 and the finish cleaning unit 352 of the cleaning apparatus 51. Namely, the second transfer arm 421 is a transfer arm dedicated to a dirty wafer W for which cleaning has not been completely finished yet.

The third transfer arm 422 transfers the wafer W whose coating film F has been ground, between the transfer-out section 321 of the grinding apparatus 50 and the front surface cleaning unit 350 of the cleaning apparatus 51. Namely, the third transfer arm 422 is a transfer arm dedicated to a dirty wafer W which has not been cleaned yet.

In the above film forming system 1, the control unit 500 is provided as illustrated in FIG. 1. The control unit 500 is, for example, a computer and has a program storage part (not illustrated). In the program storage part, a program is stored which controls the film forming treatment for the wafer W in the film forming system 1. Further, the program storage part also stores a program controlling the operation of the driving system such as the above-described various treatment apparatuses and transfer apparatuses to implement the later-described film forming treatment in the film forming system 1. Note that the program may be the one that is stored, for example, in a computer-readable storage medium H such as a computer-readable hard disk (HD), flexible disk (FD), compact disk (CD), magneto-optical disk (MO), or memory card, and installed from the storage medium H into the control unit 500.

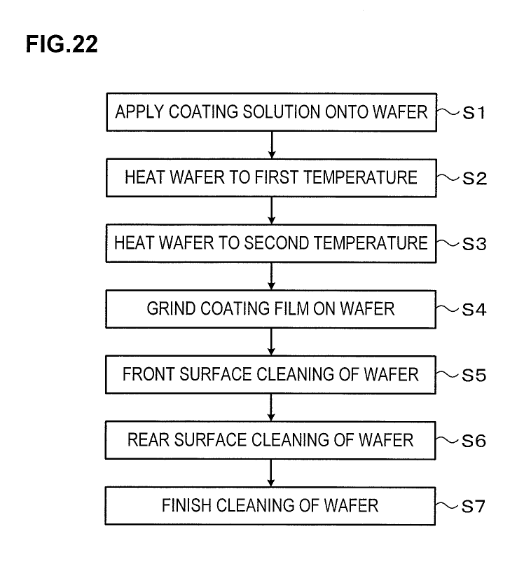

Next, the film forming method for the wafer W performed using the film forming system 1 configured as described above will be described. FIG. 22 is a flowchart illustrating an example of main steps of the film forming treatment.

First, a cassette C housing a plurality of wafers W is mounted on a predetermined cassette mounting plate 11 in the transfer-in/out station 2. Then, the wafers W in the cassette C are sequentially taken out by the wafer transfer apparatus 22 and transferred, for example, to the transition apparatus 60 in the fourth treatment block G4 in the treatment station 3.

Then, the wafer W is transferred by the wafer transfer apparatus 71 to the coating apparatus 40. The wafer W transferred in the coating apparatus 40 is delivered from the wafer transfer apparatus 71 to the chuck 290 and suction-held.

Subsequently, the arm 301 moves the coating head 302 at the waiting section 304 to a position above the outer peripheral portion of the wafer W. Then, the coating solution F is supplied from the coating solution supply source 306 to the coating head 302, and the coating solution F is exposed by the surface tension from the discharge port 302a of the coating head 302. Thereafter, the coating head 302 is lowered, and then moved in the radial direction of the wafer W with the coating solution F kept in contact with the front surface of the wafer W. Thus, the coating solution F exposed from the discharge port 302a is sequentially supplied by the action of the surface tension to the front surface of the wafer W. In this manner, the coating solution F is applied over the entire surface of the wafer W to form a coating film F (Step S1 in FIG. 22). Note that at Step S1, the coating solution F is applied in a film thickness of, for example, 20 μm to 70 μm. The adjustment of the film thickness of the coating solution F is performed by controlling the moving speed of the coating head 302 and the distance between the coating head 302 and the wafer W.

Next, the wafer W is transferred by the wafer transfer apparatus 71 to the first thermal treatment apparatus 30. When the wafer W is transferred in the first thermal treatment apparatus 30, the wafer W is delivered to the raising and lowering pins 180 which have been raised and waiting in advance. Subsequently, the raising and lowering pins 180 are lowered to mount the wafer W on the temperature regulation plate 170.

Thereafter, the temperature regulation plate 170 is moved by the drive part 173 to above the hot plate 120 along the rail 174, and the wafer W is delivered to the raising and lowering pins 131 which have been raised and waiting in advance.

Then, in the state that the wafer W supported on the raising and lowering pins 131 is not in contact with the hot plate 120, the lid body 140 is lowered to form the thermal treatment chamber K whose inside is hermetically closed by the sealing material 141. Subsequently, the pressure of the atmosphere inside the thermal treatment chamber K is reduced by the pressure reducing mechanism 160 to a predetermined degree of vacuum, for example, 20 kPa. Further, the gas supply mechanism 150 supplies the inert gas into the thermal treatment chamber K, and the pressure reducing mechanism 160 reduces the pressure of the atmosphere in the thermal treatment chamber K to keep it at the above-described degree of vacuum. Since the atmosphere in the thermal treatment chamber K is not a complete vacuum but kept at the predetermined degree of vacuum, it is possible to properly suck the wafer W by the suction pipe 123 and properly suction-hold the wafer W on the hot plate 120.

Then, the atmosphere in the thermal treatment chamber K is kept at a reduced oxygen atmosphere, for example, 10 ppm or lower. Thus, it is possible to suppress formation of an oxide film on the wafer W which is thermally treated in the thermal treatment chamber K. Note that the inert gas to be supplied into the thermal treatment chamber K is heated by the heater 154 of the gas supply mechanism 150 to, for example, 120° C. to 150° C.

Thereafter, the raising and lowering pins 131 are lowered to mount the wafer W on the hot plate 120. Then, the wafer W on the hot plate 120 is heated to a first temperature, for example, 120° C. to 150° C. (Step S2 in FIG. 22). Further, since the gas supply mechanism 150 supplies the inert gas into the thermal treatment chamber K and the pressure reducing mechanism 160 reduces the pressure of the atmosphere in the thermal treatment chamber K, a sublimate generated in the heating of the coating film F is removed without adhering to the lid body 140 and so on. Note that the heating of the wafer W at the first temperature at Step S2 is performed, for example, for 10 minutes.

Thereafter, the lid body 140 is raised, the raising and lowering pins 131 are raised, and the temperature regulation plate 170 is moved to above the hot plate 120. Subsequently, the wafer W is delivered from the raising and lowering pins 131 to the temperature regulation plate 170, and the temperature regulation plate 170 is moved to the wafer transfer region 70 side. During the movement of the temperature regulation plate 170, the wafer W is regulated to a predetermined temperature, for example, 50° C.

The wafer W is then transferred by the wafer transfer apparatus 71 to the second thermal treatment apparatus 34. The wafer W transferred in the second thermal treatment apparatus 34 is housed in the transition unit 211. Subsequently, the wafer W is transferred by the wafer transfer mechanism 221 to one hot plate 240 in the treatment container 230 of the thermal treatment unit 200. The wafer W is then delivered from the wafer transfer mechanism 221 to the hot plate 240. In this event, the transfer arm 222 of the wafer transfer mechanism 221 never interferes with the hot plate 240 since the hot plate 240 is formed with the cutouts 243.

During the time when the wafer W is being transferred to the hot plate 240, the gas supply mechanism 231 is supplying the inert gas into the treatment container 230 and the exhaust mechanism 236 is exhausting the atmosphere in the treatment container 230. Since the pressure of the atmosphere in the treatment container 230 is kept at, for example, 110 kPa as described above, it is possible to properly suck the wafer W by the suction pipe 244 and properly suction-hold the wafer W on the hot plate 240. Note that the atmosphere in the treatment container 230 is kept at a positive pressure with respect to the external atmosphere, and the atmosphere in the treatment container 230 can be maintained also when the wafer W is transferred-in/out from/to the treatment container 230.

In addition, the inside of the treatment container 230 is kept at the reduced oxygen atmosphere. This makes it possible to suppress formation of an oxide film on the wafer W which is thermally treated in the treatment container 230. Further, the inert gas to be supplied into the treatment container 230 may be, for example, at 23° C. being room temperature or may be heated to a temperature higher than room temperature by the heater 235 of the gas supply mechanism 231.

The wafer W on the hot plate 240 is then heated to the second temperature higher than the first temperature, for example, 150° C. to 250° C. (Step S3 in FIG. 22). Further, since the gas supply mechanism 231 supplies the inert gas into the treatment container 230 and the exhaust mechanism 236 reduces the pressure of the atmosphere in the treatment container 230, a sublimate generated in the heating of the coating film F is removed without adhering to treatment container 230 and so on.

Note that the heating of the wafer W at the second temperature at Step S3 is performed, for example, for 15 minutes to 1 hour. Since the heating of the wafer W at the second temperature is performed for a long time as described above, the thermal treatments of a plurality of wafers W are performed in parallel by a plurality of hot plates 240 in the treatment container 230.

The wafer W is then transferred out of the thermal treatment unit 200 by the wafer transfer mechanism 221 and transferred to the temperature regulation unit 210. The wafer W is then delivered from the wafer transfer mechanism 221 to the temperature regulation plate 253 and regulated to a predetermined temperature, for example, 23° C. being room temperature.

Thereafter, the wafer W is transferred by the wafer transfer mechanism 221 to the transition unit 212.

The wafer W is then transferred by the wafer transfer apparatus 71 to the transition apparatus 52. Subsequently, the wafer W is transferred by the first transfer arm 420 of the wafer transfer apparatus 55 to the transfer-in section 320 of the grinding apparatus 50. Thereafter, the wafer W is delivered from the transfer-in section 320 to the chuck 331 located at the waiting position P2 of the stage 330 and then suction-held thereon. After a lapse of a predetermined time, when the wafer W at the waiting position P2 becomes ready to be treated, the stage 330 is rotated to move the chuck 331 at the waiting position P2 to the treatment position P1.

At the treatment position P1, the grinding mechanism 340 is lowered to bring the wafer W held on the chuck 331 into contact with the grinding mechanism 340. In this state, the chuck 331 and the grinding mechanism 340 are individually rotated to grind the coating film F on the wafer W (Step S4 in FIG. 22). At this step S4, the coating film F is ground to have a film thickness of, for example, 15 μm.

Thereafter, the stage 330 is rotated to move the chuck 331 at the treatment position P1 to the waiting position P2. Subsequently, the wafer W is delivered from the chuck 331 at the waiting position P2 to the transfer-out section 321.

The wafer W is then transferred by the third transfer arm 422 of the wafer transfer apparatus 55 to the front surface cleaning unit 350 of the cleaning apparatus 51. The wafer W transferred in the front surface cleaning unit 350 is delivered from the third transfer arm 422 to the spin chuck 370 and suction-held thereon.

Subsequently, the nozzle arm 381 moves the pure water nozzle 383 at the waiting section 385 to a position above the central portion of the wafer W, and the scrub arm 382 moves the scrub cleaning tool 390 to a position above the wafer W. Thereafter, while the spin chuck 370 is rotating the wafer W, the pure water nozzle 383 supplies the pure water at a high pressure onto the wafer W. Then, the front surface of the wafer W is cleaned with the pure water at a high pressure from the pure water nozzle 383 and the scrub cleaning tool 390 (Step S5 in FIG. 22). Note that at Step S5, the front surface of the wafer W may be cleaned by supplying the pure water at a high pressure from the pure water nozzle 383 onto the wafer W while the pure water nozzle 383 is moving in the radial direction of the wafer W.

The wafer W is then transferred by the second transfer arm 421 to the rear surface cleaning unit 351. During the transfer of the wafer W, the first drive part 434 reverses the second transfer arm 421 to thereby reverse the front and rear surfaces of the wafer W. Namely, the rear surface of the wafer W is directed upward.

The wafer W transferred in the rear surface cleaning unit 351 is suction-held on the spin chuck 400. Subsequently, the pure water nozzle 383 supplies the pure water at a high pressure onto the wafer W which is being rotated by the spin chuck 400 to clean the rear surface of the wafer W (Step S6 in FIG. 22). Note that the cleaning of the rear surface of the wafer W at Step S6 is the same as the above-described cleaning of the front surface of the wafer W at Step S5, and therefore the description thereof is omitted. However, the cleaning by the scrub cleaning tool 390 at Step S5 is omitted at Step S6.

The wafer W is then transferred by the second transfer arm 421 to the finish cleaning unit 352. During the transfer of the wafer W, the first drive part 434 reverses the second transfer arm 421 to thereby reverse the front and rear surfaces of the wafer W. Namely, the front surface of the wafer W is directed upward. Then, in the finish cleaning unit 352, the front surface of the wafer W is subjected to finish cleaning (Step S7 in FIG. 22). Note that the finish cleaning of the front surface of the wafer W at Step S6 is the same as the above-described cleaning of the front surface of the wafer W at the Step S5, and therefore the description thereof is omitted. However, the cleaning by the scrub cleaning tool 390 at Step S5 is omitted at Step S7.

The wafer W is then transferred by the first transfer arm 420 to the transition apparatus 53. The wafer W is then transferred by the wafer transfer apparatus 71 to the transition apparatus 61, and then transferred by the wafer transfer apparatus 22 in the transfer-in/out station 2 to the cassette C on the predetermined cassette mounting plate 11. Thus, a series of the film forming treatment on the wafer W ends.

According to the above embodiment, the film forming treatment of a coating film can be performed on the wafer basis in the film forming system 1, so that the time required for the film forming treatment can be shortened. Further, the coating treatment of the coating solution F at Step S1, the low-temperature thermal treatment of the wafer W at Step S2, the high-temperature thermal treatment of the wafer W at Step S3, the grinding treatment of the coating film F at Step S4, and the cleaning treatments of the wafer W at Steps S5 to S7 are performed in one film forming system 1, so that the series of film forming treatment can be efficiently performed. Further, the above-described series of film forming treatment at Steps S1 to S7 can be performed on a plurality of wafers W in parallel in one film forming system. Accordingly, the throughput of the film forming treatment on the wafer W can be improved.

Further, in the coating apparatus 40, a so-called slit coating method is performed at Step S1 as described above. In this case, a required amount of the coating solution F can be supplied onto the wafer W. Accordingly, the supply amount of the coating solution F can be suppressed to an extremely small amount as compared, for example, with the spin coating method in which the most of the supplied coating solution scatters out of the wafer W. Especially in the case of applying the coating solution F for a film thickness of, for example, 20 μm to 70 μm onto the wafer W as in this embodiment, that effect particularly remarkably appears. Accordingly, it is possible to efficiently apply the coating solution F onto the wafer W.

Further, in the case of the conventional coating treatment on the chip basis, the coating solution is filled between the chips and the wiring substrate as described above, there is no need to grind the coating film to be formed therefrom, whereas in the case of the coating treatment on the wafer basis as in this embodiment, there is a need to grind the coating film F on the wafer W. In particular, in the case where the coating solution F is applied using the slit coating method at Step S1 as in this embodiment, there may occur unevenness in the front surface of the coating solution F and, also from this viewpoint, there is a need to grind the coating film F on the wafer W. Regarding this point, it is possible to grind the coating film F by a so-called grinder in the grinding apparatus 50 to properly adjust it at Step S4 in this embodiment.

Further, after the coating solution F is applied onto the wafer W at Step S1, the low-temperature thermal treatment of the wafer W at Step S2 and the high-temperature thermal treatment of the wafer W at Step S3 are performed. Since the thermal treatment is performed at two stages as described above, the thermal treatment of the wafer W can be efficiently performed to further improve the throughput of the film forming treatment on the wafer W.

Further, Step S2 is finished in a short time such as 10 minutes as described above, whereas Step S3 requires a long time such as 15 minutes to 1 hour. Therefore, to maintain the throughput of the film forming treatment, many hot plates 240 that perform Step S3 are required with respect to the hot plates 120 that perform Step S2. In this regard, one hot plate 120 performs treatment for one wafer W in the first thermal treatment apparatus 30 that performs Step S2, whereas the plurality of hot plates 240 perform treatment on the plurality of wafers W in parallel in the second thermal treatment apparatus 34 that performs Step S3. Accordingly, the throughput of the film forming treatment can be maintained while the apparatus configuration of the second thermal treatment apparatus 34 is simplified.

Note that though both of the low-temperature thermal treatment at Step S2 and the high-temperature thermal treatment at Step S3 are performed in this embodiment, any one of the thermal treatments may be omitted according to the required process.

Though the case where the coating material for sealing the circuits is used as the coating solution to be applied onto the wafer W has been described in the above embodiment, the coating solution to be used in the film forming system 1 is not limited to this. For example, a resist (solder resist) may be used as the coating solution. In this case, a resist as the coating solution is applied, for example, to the wafer W on which the coating film F has been formed. Then, in the film fowling system 1, the above-described Steps S1 to S7 are performed to form a resist film with a predetermined film thickness on the wafer W (on the coating film F). Note that in the case of forming the resist film on the wafer W as describe above, the thermal treatment after the application of the resist may be only the low-temperature thermal treatment in some case. In this case, the high-temperature thermal treatment of the wafer W at Step S3 may be omitted.

Though the film formation of the coating film F and the film formation of the resist are separately performed in the film forming system 1 in the above embodiment, both of the film formation of the coating film F and the film formation of the resist may be performed in one film forming system 1. In this case, it is only necessary to apply the coating solution F onto the wafer W, for example, in the coating apparatus 40 and apply the resist onto the wafer W in the coating apparatus 41. The other first thermal treatment apparatuses 30 to 33, second thermal treatment apparatus 34, grinding apparatus 50, and cleaning apparatus 51 can be used in common to the film forming treatment of the coating film F and the film forming treatment of the resist.

Though the coating head 302 is moved to apply the coating solution F onto the wafer W in the coating apparatus 40 at Step S1 in the above embodiment, the chuck 290 that holds the wafer W may be moved. Alternatively, both of the coating head 302 and the chuck 290 may be moved.

Though the coating solution F is applied using the so-called slit coating method in the coating apparatus 40 at Step S1 in the above embodiment, for example, a capillary coating method may be used. The capillary coating method is a method of applying the coating solution F to the lower surface of the wafer W which is reversely held while the coating solution F is caused to rise from below by the capillary phenomenon. Concretely, the coating solution F is supplied to the coating head with the discharge port in a slit form directed upward. The coating solution F rises in the coating head by the capillary phenomenon and is exposed from the discharge port of the coating head by the surface tension. Then, the coating head is moved in the radial direction of the wafer W with the coating solution F kept in contact with the wafer W. Thus, the coating solution F is applied onto the wafer W.

Further, at Step S1 in the above embodiment, the coating solution F may be applied onto the wafer W using a so-called spin coating method.

Though the coating film F is ground by the so-called grinder in the grinding apparatus 50 at Step S4 in the above embodiment, the method of grinding the coating film F is not limited to this. The coating film F on the wafer W may be ground by, for example, the chemical mechanical polishing (CMP).

After the grinding of the coating film F at Step S4 in the above embodiment, heat treatment may further be performed on the coating film F. For example, when the coating film F is polished by the grinding mechanism 340, a polishing remnant may remain. In this case, the wafer W is heated, for example, by the heating mechanism (not illustrated) provided in the grinding apparatus 50. This heats and softens the coating film F and thereby further adjusts its front surface.

Further, after the grinding of the coating film F at Step S4, a solvent gas for the coating film F may be supplied to the coating film F. In this case, the front surface of the coating film F dissolves with the solvent, whereby the front surface is further ground. Note that both of the supply of the solvent gas and the above-described heat treatment may be performed, in which case the grinding of the coating film F can be efficiently performed.

Further, after the grinding of the coating film F at Step S4, electrolytic polishing may further be performed. In this case, the polishing remnant can be polished by electric charges concentrating on the polishing remnant, so that the coating film F can further be adjusted.

Further, after the grinding of the coating film F at Step S4, the coating film F may further be pressed. In this case, the coating film F can further be adjusted.

A preferred embodiment of the present invention has been described above with reference to the accompanying drawings, but the present invention is not limited to the embodiment. It should be understood that various changes and modifications are readily apparent to those skilled in the art within the scope of the technical spirit as set forth in claims, and those should also be covered by the technical scope of the present invention.

What is claimed is:

1. A film forming system for forming a coating film on a substrate having a plurality of circuits formed on a front surface thereof, said system comprising:
a treatment station that performs a predetermined treatment on the substrate; and
a transfer-in/out station configured to retain a plurality of substrates and transfer the substrates in/out from/to said treatment station,
said treatment station comprising:
a coating apparatus that applies a coating solution onto the front surface of the substrate to form a containing film;
a thermal treatment apparatus that thermally treats the substrate on which the coating film has been formed;
a grinding apparatus that grinds the coating film on the front surface of the substrate which has been thermally treated;
a cleaning apparatus that cleans the substrate whose coating film has been ground; and
a transfer region for transferring the substrate to said coating apparatus, said thermal treatment apparatus, said grinding apparatus, and said cleaning apparatus.

2. The film forming system according to claim 1,
wherein the coating solution is a coating material for sealing the circuits.

3. The film forming system according to claim 1,
wherein said thermal treatment apparatus has a first thermal treatment apparatus that thermally treats the substrate at a first temperature, and a second thermal treatment apparatus that thermally treats the substrate at a second temperature higher than the first temperature.

4. The film forming system according to claim 3,
wherein a plurality of said first thermal treatment apparatuses are provided, and each of said first thermal treatment apparatuses has a first treatment container that is configured to hermetically close an inside thereof and a first thermal treatment plate that is provided in said first treatment container and mounts and thermally treats the substrate thereon, and
wherein said second treatment apparatus has a second treatment container that is configured to hermetically close an inside thereof and a plurality of second thermal treatment plates that are provided in said second treatment container and mount and thermally treat the substrates thereon.

5. The film forming system according to claim 1,
wherein the coating solution is a resist.

6. The film forming system according to claim 1,
wherein said coating apparatus comprises a coating head that is formed with a discharge port for the coating solution in a slit shape, and a moving mechanism that relatively moves the coating head and the substrate.

7. The film forming system according to claim 1,
wherein said grinding apparatus comprises a polishing mechanism that polishes the coating film.
